(19) United States
(12) Patent Application Publication
(10) Pub. No.: US 2006/0268649 A1
(43) Pub. Date: Nov. 30, 2006

(54) Memory interface

(75) Inventors: Miho Tokieda, Kanagawa (JP); Kenji Matsushita, Osaka (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/440,159

(22) Filed: May 25, 2006

(30) Foreign Application Priority Data
May 25, 2005 (JP) 2005-152616

(51) Int. Cl. G11C 8/00

(52) U.S. Cl. 365/230.03

(57) ABSTRACT

In a memory interface, a buffer is composed of a plurality of blocks corresponding to respective corresponding banks in a multibank memory. A bank determiner stores an input memory access parameter into a corresponding block. A buffer controller performs an output control of the buffer so that memory access parameters are output from the buffer in order of the respective corresponding banks in the multibank memory. A row address comparator compares row addresses of consecutively output memory access parameters for access to the same bank. When accesses are consecutively performed with respect to the same bank and the same row, a command generator skips generating a precharge command to be issued after memory access for a preceding memory access parameter.

### CROSS REFERENCE TO RELATED APPLICATIONS

This Non-provisional application claims priority under 35 U.S.C. §119(a) on Patent Application 2005-152616 filed in Japan on May 25, 2005, the entire contents of which are hereby incorporated by reference.

### BACKGROUND OF THE INVENTION

1. Field of the Invention

The present invention relates to a memory interface, and more particularly, to an access control technique for multibank memories, such as an SDRAM (Synchronous Dynamic Random Access Memory) and the like.

2. Description of the Related Art

FIG. 21 illustrates a configuration of a conventional memory interface. When a functional device (not shown, also referred to as a bus master) accesses an SDRAM, the bus master outputs a bus request signal to a bus arbitrator 100. When an internal bus (not shown) is not used by any bus master, the bus arbitrator 100 gives the bus master a right to use the internal bus (also referred to as a bus right). The bus master given the bus right by the bus arbitrator 100 outputs a memory access parameter including a command, a start address, a transfer word length, data, and the like, to the memory interface. The memory access parameter from the bus master is selected, depending on the result of arbitration performed by the bus arbitrator 100, and the selected memory access parameter is transferred to a command generator 200. The command generator 200 generates a memory access command for the memory access parameter from the bus master, and accesses the SDRAM.

Conventionally, regarding access to a multibank memory, such as an SDRAM or the like, a relationship between before and after memory access is not taken into consideration, and all banks in the SDRAM are caused to be in a precharged state when a bus master having a bus right ends memory access. Therefore, even when there are consecutive addresses for memory access parameters, an active command and a precharge command are invariably issued upon access to the SDRAM, resulting in inefficient access to the SDRAM. As a technique for solving this problem, there is a known memory interface in which an address of an issued memory request (memory access parameter) is compared with an address of the following memory request, and based on the result of the comparison, SDRAM access is optimized.

According to the above-described known memory interface, when consecutive memory access parameters for memory access to the same bank and the same row are input, optimal SDRAM access is achieved. However, when memory access parameters for different banks or different row addresses are alternately input, the effect is not sufficient.

### SUMMARY OF THE INVENTION

In view of the above-described problems, an object of the present invention is to provide a memory interface which performs an access control of a multibank memory, in which, even when memory access parameters for different banks are alternately input, issuance of a memory access command is made eligible, thereby improving memory access efficiency.

To achieve the object, a memory interface for controlling access of a plurality of bus masters to a multibank memory, comprises a buffer capable of storing a plurality of memory access parameters from the plurality of bus masters, a buffer controller for performing an output control of the buffer so that the memory access parameters stored in the buffer are output in order of respective corresponding banks in the multibank memory, and a command generator for generating a command for access to the multibank memory based on the memory access parameters output from the buffer. Here, when the command generator successively receives memory access parameters for access to the same bank and the same row in the multibank memory, the command generator skips generating a precharge command to be issued after memory access to the preceding memory access parameter.

Thereby, memory access parameters input to the memory interface are output in order of respective corresponding banks in the multibank memory, irrespective of the order of input of the memory access parameters, and when memory access parameters for memory access to the same bank and the same row are consecutively output, it is skipped to generate a precharge command. Therefore, even when memory access parameters for memory access to different banks are alternately input, issuance of a memory access command is made eligible, thereby improving memory access efficiency.

Preferably, the buffer is composed of a plurality of blocks corresponding to respective banks in the multibank memory. The memory interface comprises a bank determiner for determining a bank for a memory access parameter input into the memory interface, and storing the memory access parameter into a block in the buffer corresponding to the determined bank. Here, the buffer controller performs an output control of the buffer so that blocks are successively selected, and memory access parameters are consecutively output from the selected block.

Thereby, memory access parameters input to the memory interface are stored into corresponding blocks in the buffer composed of blocks corresponding to respective banks in the multibank memory, so that it is easier for the buffer controller to perform an output control of memory access parameters in order of the respective corresponding banks in the multibank memory.

More preferably, the memory interface comprises a register for storing information about a configuration of the buffer. Here, the buffer is composed of a plurality of blocks based on the information stored in the register.

Thereby, even when a multibank memory having any bank configuration is connected to the memory interface, the bank configuration can be flexibly handled by setting the bank configuration in the register.

More preferably, the memory interface comprises a counter for counting the number of access requests to each bank in the multibank memory based on a result of the determination by the bank determiner. Here, the buffer changes a size of each of the plurality of blocks for each predetermined time interval, based on a result of the count of the counter.

Thereby, the buffer configuration is changed in predetermined time intervals, depending on the frequency of access to each bank in the multibank memory during the time when the system is operating, thereby making it possible to effectively utilize the buffer resource.

More preferably, the memory interface comprises an arbitration instructor for referencing a fullness of each block in the buffer, and instructing a bus arbitrator to preferentially give a bus use right to a bus master which requests access to a bank corresponding to a block having a relatively low fullness, among the plurality of bus masters.

Thereby, bus arbitration is performed, depending on the fullness of each block in the buffer, thereby avoiding overflow of the buffer, resulting in prevention of a reduction in memory access efficiency.

More preferably, the memory interface comprises a timing designator for designating timing for selection of the blocks with respect to the buffer controller. Here, the buffer controller successively selects the blocks in accordance with the timing designated by the timing designator.

Thereby, it is possible to change timing for selection of blocks in the buffer by the buffer controller, thereby making it possible to flexibly make memory access eligible, depending on the application.

Further, preferably, the timing designator references a fullness of each block in the buffer, and designates the timing so that an output time of a memory access parameter from a block having a relatively high fullness is relatively long.

Thereby, occurrence of overflow of the buffer is suppressed, resulting in an improvement in memory access efficiency.

More preferably, the memory interface comprises a command determiner for determining whether the input memory access parameter is for write access or read access. Here, when the command determiner determines that the input memory access parameter is for read access, the buffer controller preferentially selects a block in the buffer corresponding to a bank for the input memory access parameter which is a determination target of the bank determiner.

Thereby, a time required to wait for read access is reduced, and system response is improved.

More preferably, the memory interface comprises an overtake determiner for determining whether or not the input memory access parameter can be output earlier than a memory access parameter which is already stored in the buffer and is for access to the same bank in the multibank memory. Here, when the command determiner determines that the input memory access parameter is for read access, the overtake determiner references a memory access parameter already stored in a block in the buffer corresponding to a bank for the input memory access parameter which is a determination target of the bank determiner, and when the referenced memory access parameter is for write access to a row different from that for read access for the input memory access parameter, determines that the input memory access parameter can be output earlier than the referenced memory access parameter. Also, the buffer controller performs an output control of the buffer so that the memory access parameter determined by the overtake determiner to be able to be output earlier is preferentially output from the preferentially selected block.

Thereby, a memory access parameter for read access is output earlier than a memory access parameter for write access to the same bank which is input earlier and is stored, thereby further reducing the read access waiting time, resulting in a further improvement in system response.

More specifically, the memory interface comprises a row address comparator for comparing row addresses for two memory access parameters for access to the same bank in the multibank memory, the two memory access parameters being successively output from the buffer. Here, when the row address comparator indicates that the row addresses for the two memory access parameters are the same, the command generator skips generating the precharge command.

Further specifically, when the row address comparator indicates that the row addresses for the two memory access parameters are not the same, the buffer controller performs an output control of the buffer so that a memory access parameter corresponding to another bank in the multibank memory is output. Also, when the row address comparator indicates that the row addresses for the two memory access parameters are not the same, the command generator generates a command for memory access for the memory access parameter corresponding to the other bank earlier than the command for memory access for the following memory access parameter.

Thereby, when a row address for the preceding access of consecutive memory accesses to the same bank is different from a row address for the following access, a command for access to another bank is generated earlier than generation of a command for the following access. Therefore, after end of the following access, another bank can be quickly accessed, resulting in an improvement in memory access efficiency.

On the other hand, preferably, the memory interface comprises an address increment calculator for calculating increments of addresses for the plurality of memory access parameters for access to the same bank in the multibank memory, the plurality of memory access parameters being successively output form the buffer; and an increment summing section for summing the increments calculated by the address increment calculator. Here, the command generator generates a command for transferring data corresponding to an address for a leading one of the plurality of memory access parameters, and following data corresponding to the sum of the increments calculated by the increment summing section, together in one access.

Thereby, when a plurality of memory access parameters within a predetermined address range are consecutively issued, commands are not generated for these memory access parameters separately, and a command which can transfer the data together in one access is generated, resulting in an improvement in memory access efficiency.

More preferably, the memory interface comprises a burst transfer determiner for, when a memory access parameter for a burst transfer start request is output from the buffer, determining a start address, a transfer length, and a request source bus master for the request based on the memory access parameter, and an address generator for generating addresses for burst transfer having a predetermined transfer length and successively storing the addresses into the buffer, until data transfer is completed in an amount corresponding to the transfer length from the start address, the transfer length and the start address being determined by the burst transfer determiner. Here, the buffer controller performs an output control of the buffer so that a memory access parameter corresponding to a bank for burst transfer having the predetermined transfer length in the multibank memory is output.

Thereby, even when the capacity of the buffer is relatively small, it is possible to support burst transfer while improving memory access efficiency.

More preferably, the burst transfer determiner determines whether or not access to a bank in the multibank memory is ended by burst transfer having the predetermined transfer length for a memory access parameter output from the buffer. The buffer controller performs an output control of the buffer so that, when the burst transfer determiner determines that the access is ended, a memory access parameter corresponding to the next bank in the multibank memory is output. The command generator, when the burst transfer determiner determines that the access is ended, generates an active command for the next bank, following generation of a command for a memory access parameter output from the buffer.

Thereby, when banks are switched during requested burst transfer, the next bank is caused to be active in advance, so that the burst transfer is not suspended, resulting in a further improvement in memory access efficiency.

More preferably, the burst transfer determiner determines whether or not burst transfer having the predetermined transfer length goes across a bank border in the multibank memory. The buffer controller performs an output control of the buffer so that, when the burst transfer determiner determines that the burst transfer having the predetermined transfer length goes across the bank border, a memory access parameter corresponding to the bank beyond the border in the multibank memory is output. The command generator, when the burst transfer determiner determines that the burst transfer having the predetermined transfer length goes across the bank border, generates an active command for a bank beyond the border before generation of a command for the burst transfer having the predetermined transfer length.

Thereby, when burst transfer having a predetermined transfer length goes across a bank border partway therethrough, a bank beyond the bank border is caused to be active in advance, so that the burst transfer is not suspended, resulting in a further improvement in memory access efficiency.

### BRIEF DESCRIPTION OF THE DRAWINGS

FIG. 1 is a diagram illustrating a configuration of a memory interface according to a first embodiment of the present invention.

FIG. 2 is a diagram illustrating an exemplary data structure of a memory access parameter.

FIGS. 3A and 3B are timing charts for explaining an operation of the memory interface of FIG. 1.

FIG. 4 is a diagram illustrating a configuration of a memory interface according to a second embodiment of the present invention.

FIGS. 5A, 5B and 5C are diagrams illustrating exemplary block configurations of a buffer.

FIG. 6 is a diagram illustrating a configuration of a memory interface according to a third embodiment of the present invention.

FIG. 7 is a diagram illustrating a configuration of a memory interface according to a fourth embodiment of the present invention.

FIG. 8 is a diagram illustrating a configuration of a memory interface according to a fifth embodiment of the present invention.

FIG. 9 is a diagram illustrating a configuration of a memory interface according to a sixth embodiment of the present invention.

FIGS. 10A and 10B are timing charts for explaining an operation of the memory interface of FIG. 9.

FIG. 11 is a diagram illustrating a configuration of a memory interface according to a seventh embodiment of the present invention.

FIG. 12 is a diagram illustrating a configuration of a memory interface according to an eighth embodiment of the present invention.

FIG. 13 is a diagram illustrating a configuration of a memory interface according to a ninth embodiment of the present invention.

FIGS. 14A and 14B are timing charts for explaining an operation of the memory interface of FIG. 13.

FIG. 15 is a diagram illustrating a configuration of a memory interface according to a tenth embodiment of the present invention.

FIG. 16 is a diagram illustrating an exemplary data structure of a memory access parameter for a burst transfer start request.

FIG. 17 is a diagram illustrating a configuration of a memory interface according to an eleventh embodiment of the present invention.

FIGS. 18A and 18B are timing charts for explaining an operation of the memory interface of FIG. 17.

FIGS. 19A and 19B are timing charts for explaining an operation of the memory interface of FIG. 17.

FIG. 20 is a diagram illustrating a configuration of a memory interface according to a twelfth embodiment of the present invention.

FIG. 21 is a diagram illustrating a configuration of a conventional memory interface.

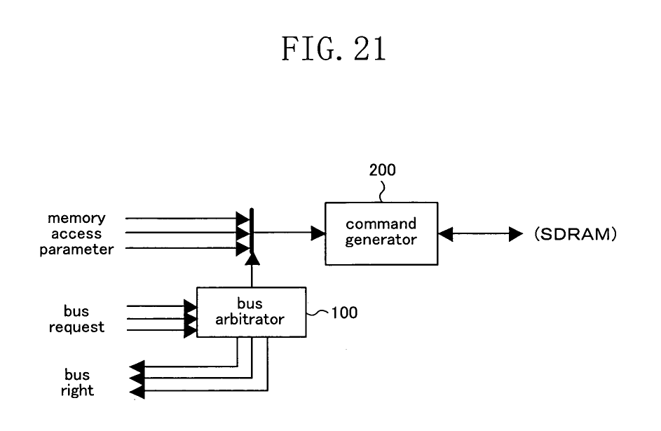

### DETAILED DESCRIPTION OF THE PREFERRED EMBODIMENTS

Hereinafter, embodiments of the present invention will be described with reference to the accompanying drawings.

### FIRST EMBODIMENT

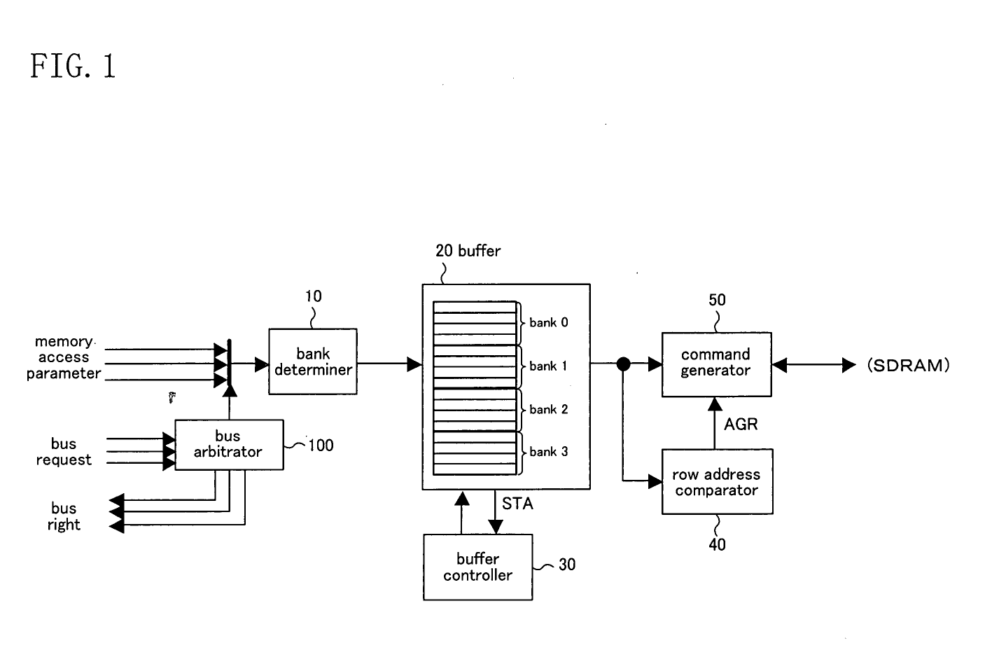

FIG. 1 illustrates a configuration of a memory interface according to a first embodiment of the present invention. The memory interface of this embodiment comprises a bank determiner 10, a buffer 20, a buffer controller 30, a row address comparator 40, and a command generator 50.

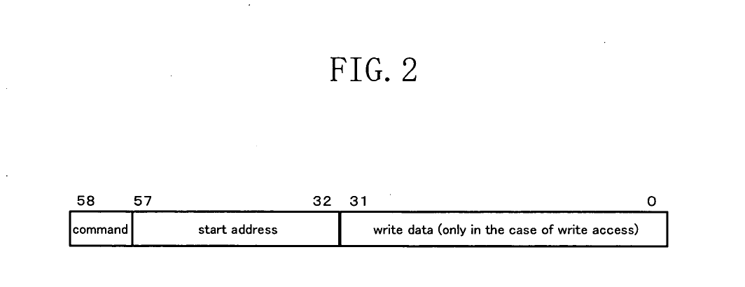

The bank determiner 10 determines which bank in an SDRAM (not shown) is accessed with respect to a memory access parameter output from a functional device (not shown, also referred to as a bus master) selected by a bus arbitrator 100, based on several bits of an address included in the memory access parameter. FIG. 2 illustrates an exemplary data structure of the memory access parameter. For example, the memory access parameter includes an address (start address) of an SDRAM, a command, and in the case of write access, information, such as data or the like.

The buffer 20 stores a plurality of memory access parameters from the bus master. The buffer 20 is divided into blocks corresponding to respective banks of the SDRAM, and each block stores a memory access parameter for which a corresponding bank has been determined by the bank determiner 10.

The buffer 20 outputs to the buffer controller 30 a signal STA which indicates the stored state of a memory access parameter for each divided block. For example, the signal STA indicates that a memory access parameter is stored in a corresponding block when it is at a Hi level, and indicates that a corresponding block is empty when it is at a Lo level. When receiving the Hi-level signal STA from the buffer 20, the buffer controller 30 starts an output control of the buffer 20. Specifically, the buffer controller 30 successively selects blocks in the buffer 20, and performs an output control of the buffer 20 so that memory access parameters are successively output from the selected block until the selected block becomes empty or a predetermined time (also referred to as a maximum select time) elapses. In other words, memory access parameters are output in order of corresponding banks in the SDRAM, but not in order of input into the memory interface. Note that the reason why another block is selected after the maximum select time has elapsed is that memory access to a specific bank is prevented from being disadvantageously continued for a long period of time.

The row address comparator 40 compares row addresses included in two memory access parameters consecutively output from the same block of the buffer 20. For example, a signal AGR indicating the result of the comparison of the row addresses, indicates that the row addresses are the same when it is at a Hi level, and indicates that the row addresses are not the same when it is at a Lo level.

The command generator 50 generates a command for access to the SDRAM, based on a memory access parameter output from the buffer 20. The command generator 50 references the signal AGR so as to generate the command, and when the row addresses of consecutive memory access parameters for access to the same bank are the same, skips generating a precharge command which is to be issued after memory access for a preceding memory access parameter. On the other hand, when the row addresses are not the same, the command generator 50 ordinarily generates a command, i.e., generates a precharge command after generating a command for a preceding memory access parameter, and following this, generates an active command and an access command for the following memory access parameter.

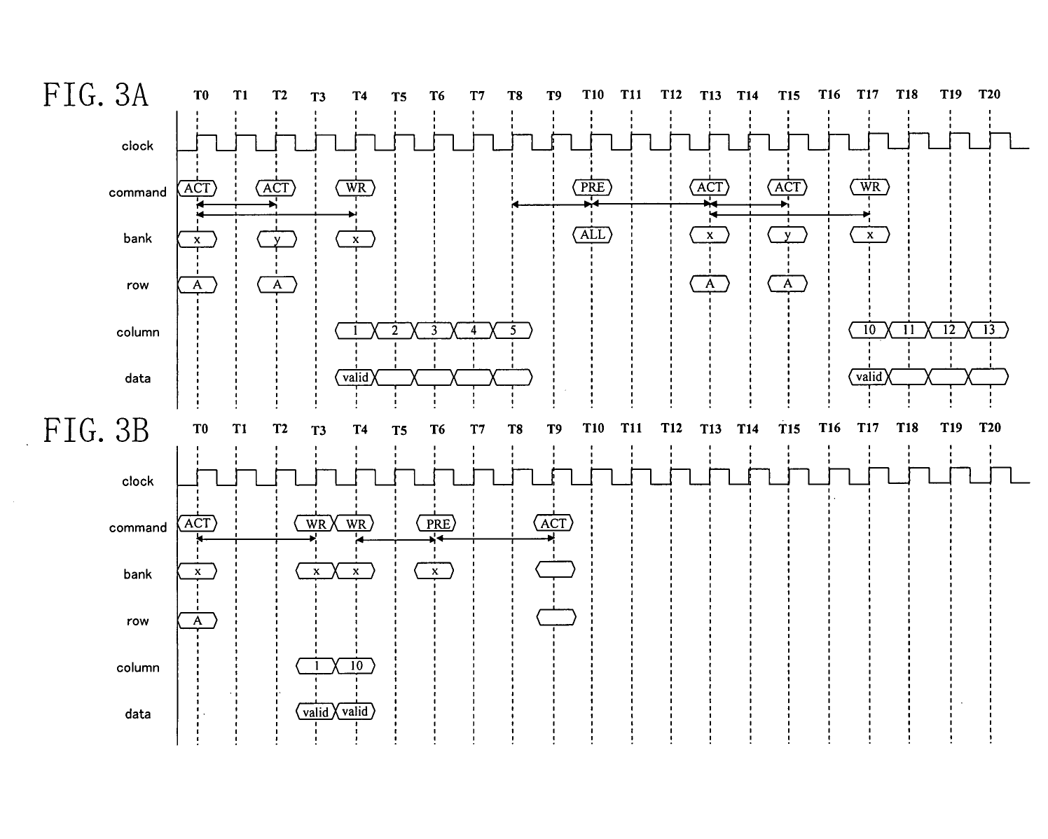

FIGS. 3A and 3B are timing charts for explaining an operation of the memory interface of this embodiment. FIG. 3A is a timing chart when the row addresses of memory access parameters consecutively output from the buffer 20 are not the same. In this case, after a write command for a preceding memory access parameter is issued at time T4, a precharge command is issued with respect to all banks of the SDRAM at time T10, and a write command for the following memory access parameter is issued at time T17. On the other hand, FIG. 3B is a timing chart when the row addresses of memory access parameters consecutively output from the buffer 20 are the same. In this case, after a write command for a preceding memory access parameter is issued at time T3, a precharge command is not issued, and a write command for the following memory access parameter is issued at time T4.

As described above, according to this embodiment, memory access parameters for memory access to the same bank in an SDRAM are consecutively processed irrespective of the order of input of the memory access parameters from a bus master, and when memory access is consecutively performed with respect to the same row, an unnecessary precharge command is not generated. Thereby, even when memory access parameters for memory access to different banks are alternately input, issuance of a memory access command is made eligible, resulting in an improvement in memory access efficiency.

### SECOND EMBODIMENT

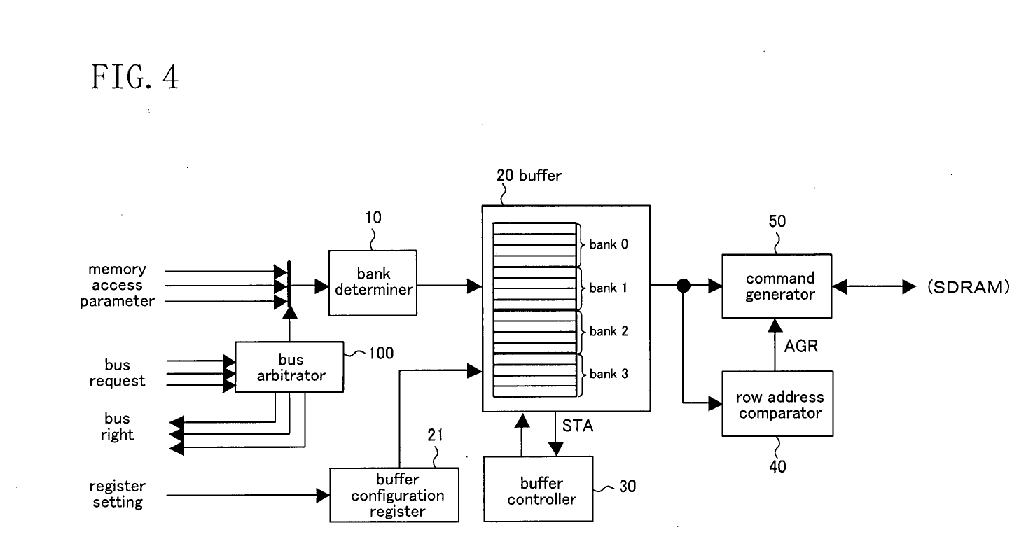

FIG. 4 illustrates a configuration of a memory interface according to a second embodiment of the present invention. The memory interface of this embodiment has the same configuration as that of the memory interface of the first embodiment, except that a buffer configuration register 21 is additionally provided. Hereinafter, only a difference between the first and second embodiments will be described.

The buffer configuration register 21 stores information about a configuration of the buffer 20. The information is set by, for example, a CPU (Central Processing Unit) or a DSP (Digital Signal Processor) which controls the memory interface. The information also corresponds to the number of banks in an SDRAM connected to the memory interface. In other words, the buffer 20 is optimally configured, depending on the number of banks in the SDRAM.

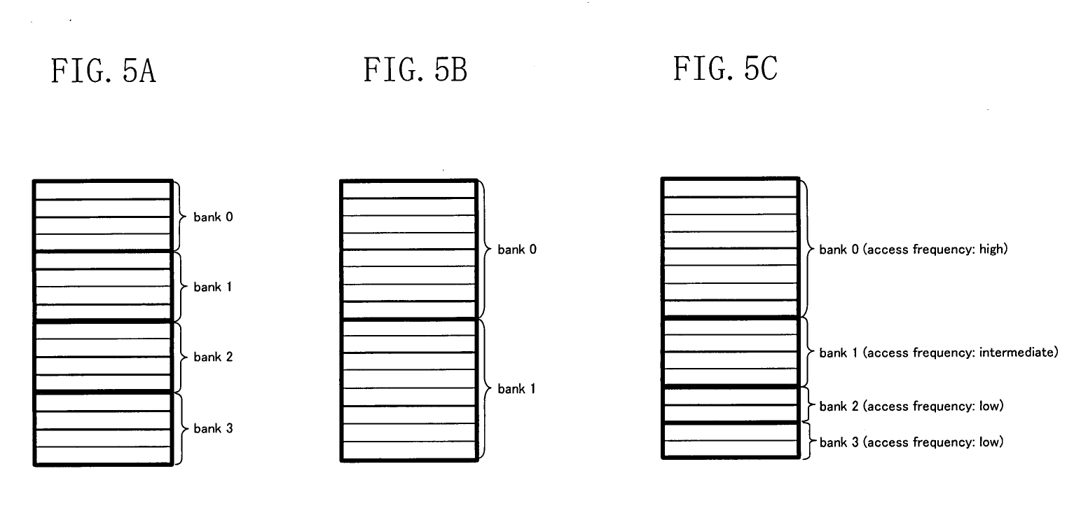

The buffer 20 determines a block configuration by referencing the information stored in the buffer configuration register 21. FIGS. 5A, 5B and 5C illustrate exemplary block configurations of the buffer 20. When the number of banks in the SDRAM is “4”, the buffer configuration register 21 stores, for example, a numerical value “4”, and the buffer 20 has four blocks, i.e., bank 0 to bank 3, as illustrated in FIG. 5A. On the other hand, when the number of banks in the SDRAM is “2”, the buffer configuration register 21 stores, for example, a numerical value “2”, and the buffer 20 has two blocks, i.e., bank 0 and bank 1, as illustrated in FIG. 5B.

Sizes of the blocks of the buffer 20 do not necessarily need to be equal to each other. The sizes of the blocks may be different from each other as illustrated in FIG. 5C, depending on the frequencies of access to the respective banks in the SDRAM. In the case of the configuration of FIG. 5C, eight stages of a total of “16” stages in the buffer 20 are allocated to bank 0 having a “high” access frequency, four stages are allocated to bank 1 having an “intermediate” access frequency, and two stages are allocated to each of bank 2 and bank 3 having a “low” access frequency.

Note that, when there is a difference in size between blocks in the buffer 20, the buffer configuration register 21 needs to store information about the access frequency or the like of each block in addition to the number of banks in the SDRAM. For example, when the “high”, “intermediate”, and “low” access frequencies are taken into consideration with respect to the four banks, the buffer configuration register 21 may store 2-bit information indicating an access frequency for each of the four banks, i.e., a total of 8-bit information.

As described above, according to this embodiment, the number of banks in an SDRAM, and in some cases, the frequency of access to each bank or the like, are taken into consideration so as to appropriately configure blocks in a buffer, thereby improving memory access efficiency, and effectively utilizing a buffer resource.

### THIRD EMBODIMENT

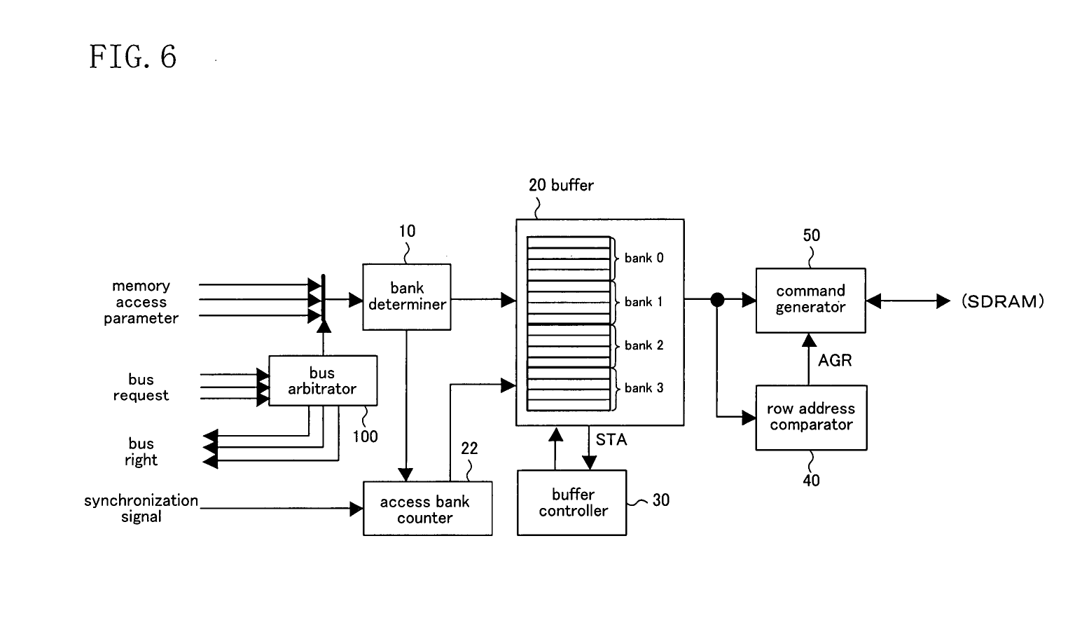

FIG. 6 illustrates a configuration of a memory interface according to a third embodiment of the present invention. The memory interface of this embodiment has the same configuration as that of the memory interface of the second embodiment, except that an access bank counter 22 is provided in place of the buffer configuration register 21. Hereinafter, only a difference between the second and third embodiments will be described.

The access bank counter 22 counts the number of access requests to each bank in an SDRAM during a predetermined time interval, i.e., an access frequency. Specifically, the access bank counter 22 counts the frequency of access to a bank every time the bank is determined with respect to a memory access parameter by the bank determiner 10, during a predetermined time interval indicated with a given synchronization signal. The buffer 20 references the access frequency of each bank counted by the access bank counter 22, and reconfigures the blocks in the predetermined time intervals. This block configuration is the same as that which has been described in the second embodiment. Note that, as the synchronization signal, for example, a horizontal synchronization signal for an image display process can be used.

As described above, according to this embodiment, the block configuration of a buffer is dynamically changed, depending on the access frequency of each bank in an SDRAM. Particularly, in a system in which access is concentrated on a specific bank in an SDRAM, more efficient memory access, and more effective utilization of a buffer resource are achieved.

### FOURTH EMBODIMENT

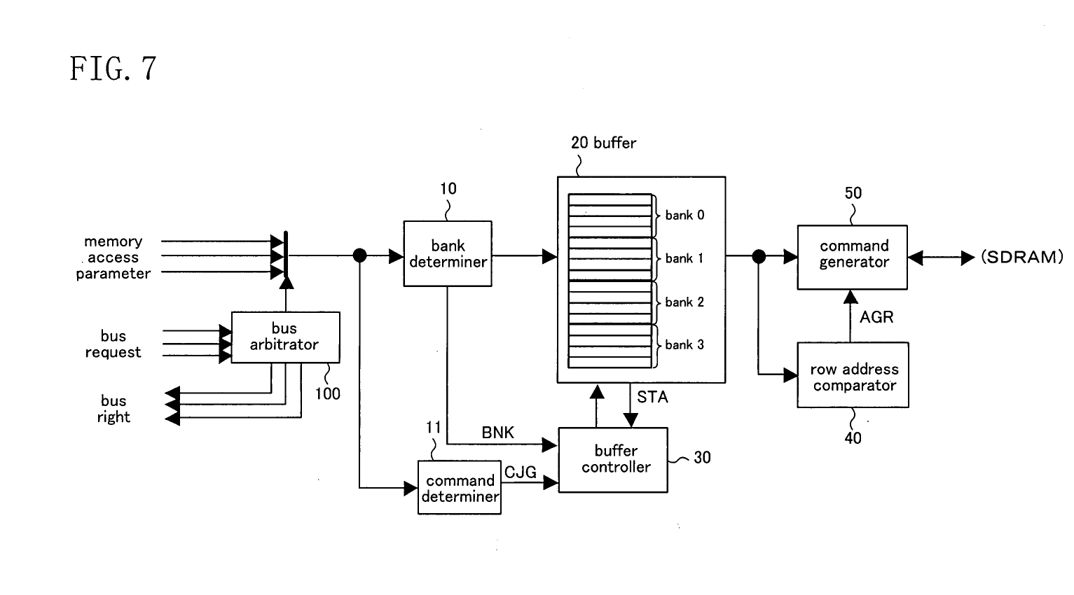

FIG. 7 illustrates a configuration of a memory interface according to a fourth embodiment of the present invention. The memory interface of this embodiment has the same configuration as that of the memory interface of the first embodiment, except that a command determiner 11 is additionally provided. Hereinafter, only a difference between the first and fourth embodiments will be described.

The command determiner 11 determines whether a memory access parameter input to the memory interface is for write access or read access, based on command information (see FIG. 2) included in the memory access parameter. The result of the determination is output as a signal CJG to the buffer controller 30. For example, the signal CJG indicates write access when it is at a Hi level, and read access when it is at a Lo level.

When the signal CJG is at the Lo level, the buffer controller 30 performs an output control of the buffer 20 so that a block corresponding to a bank for the input memory access parameter is preferentially selected, the bank being indicated with a signal BNK output from the bank determiner 10, and memory access parameters are output from the selected block until the block becomes empty. Specifically, in the memory interface of this embodiment, when an input of a memory access parameter for read access is detected, a block corresponding to a bank for the input memory access parameter in the buffer 20 is preferentially selected, and all memory access parameters stored in the block are processed. Note that all memory access parameters stored in a block corresponding to the same bank as that for read access are processed before performing read access, data can be serially processed. The reason why a higher priority is given to read access than that of write access is that, in the case of the write access request, the bus master does not necessarily need to wait for the result of the process, and in the case of the read access request, the next process cannot be performed until the result of the process is received.

As described above, according to this embodiment, a memory access parameter for read access is preferentially processed, so that a wait time for a read access request is reduced, resulting in an improvement in system response.

### FIFTH EMBODIMENT

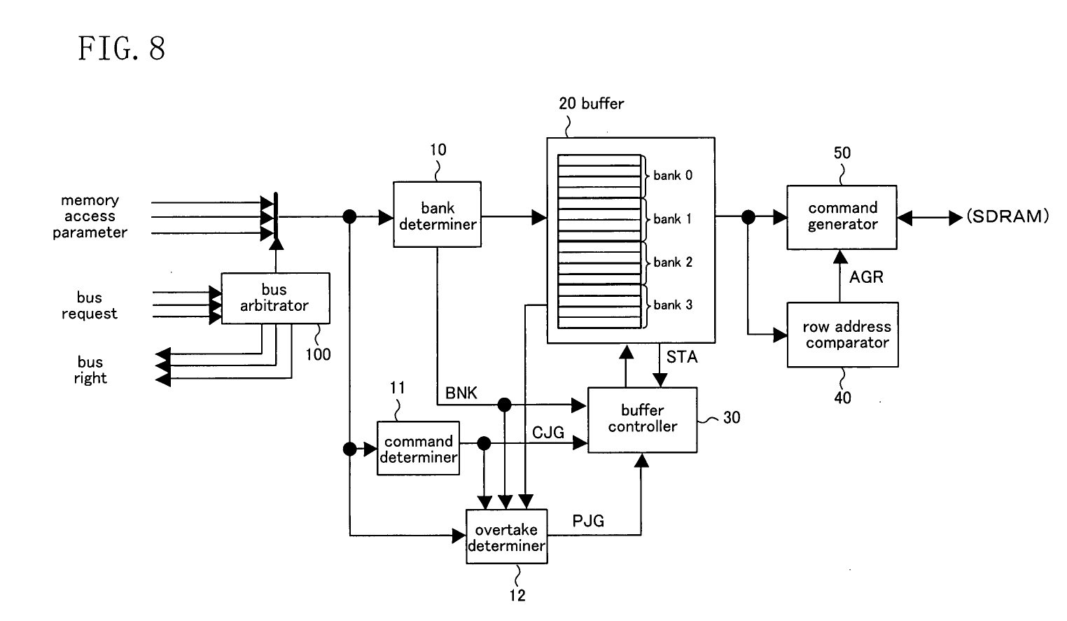

FIG. 8 illustrates a configuration of a memory interface according to a fifth embodiment of the present invention. The memory interface of this embodiment has the same configuration as that of the memory interface of the fourth embodiment, except that an overtake determiner 12 is additionally provided. Hereinafter, only a difference between the fourth and fifth embodiments will be described.

The overtake determiner 12 determines whether or not a memory access parameter for read access which is input later can be processed earlier than a memory access parameter already stored in the buffer 20, i.e., the later memory access parameter can overtake the earlier memory access parameter. Specifically, when the signal CJG is at the Lo level, the overtake determiner 12 references a memory access parameter for write access which is already stored in a block corresponding to a bank of the buffer 20 indicated with the signal BNK, and compares the row address of the memory access parameter with the row address of a memory access parameter for read access which is input later. When these row addresses are not the same, it is determined that the memory access parameter input later can be processed earlier than the memory access parameter input earlier, and the result of the determination is output as a signal PJG. For example, the signal PJG indicates that overtaking is possible when it is at a Hi level, and indicates that overtaking is not possible when it is at a Lo level.

When the signal CJG is at the Lo level, the buffer controller 30 performs an output control of the buffer 20 so that a block corresponding to a bank for the input memory access parameter is preferentially selected, the bank being indicated with the signal BNK output from the bank determiner 10, and when the signal PJG is at the Hi level, a memory access parameter for read access which is stored later into the selected block is preferentially output. Specifically, in the memory interface of this embodiment, when an input of a memory access parameter for read access is detected, a block corresponding to a bank for the input memory access parameter in the buffer 20 is preferentially selected, and when it is determined that the input memory access parameter can be processed earlier than a memory access parameter already stored in the block, the memory access parameter for read access is processed earlier.

As described above, according to this embodiment, a higher priority is given to a process for a memory access parameter for read access, so that a wait time for a read access request is further reduced, resulting in a further improvement in system response.

### SIXTH EMBODIMENT

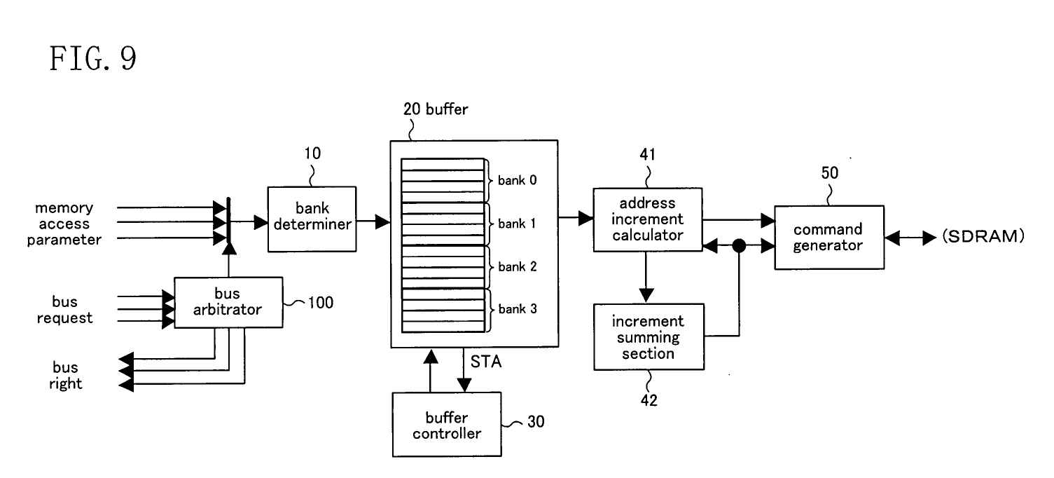

FIG. 9 illustrates a configuration of a memory interface according to a sixth embodiment of the present invention. The memory interface of this embodiment has the same configuration as that of the memory interface of the first embodiment, except that an address increment calculator 41 and an increment summing section 42 are provided in place of the row address comparator 40. Hereinafter, only a difference between the first and sixth embodiments will be described.

The address increment calculator 41 calculates an increment of column addresses included in two memory access parameters consecutively output from the same block in the buffer 20. The increment summing section 42 sums increments output from the address increment calculator 41, and outputs the sum. For example, when four consecutive memory access parameters include four consecutive column addresses, the column addresses increase in units of “1”, and the sum of the increments is “3”.

When the sum of the increment sum output from the increment summing section 42 and a column address increment calculated immediately before is larger than a predetermined value, or a block in the buffer 20 which is an output source of a memory access parameter is switched, the address increment calculator 41 outputs a leading one of a series of memory access parameters whose column addresses have been subjected to the increment summation. Note that the above-described predetermined value is assumed to be the length of data which can be transferred at one time by burst transfer.

The command generator 50 uses a column address indicated by a memory access parameter output from the address increment calculator 41 as a leading address to generate, and a command for burst transfer of data corresponding to the leading address and following data corresponding to the increment sum output from the increment summing section 42.

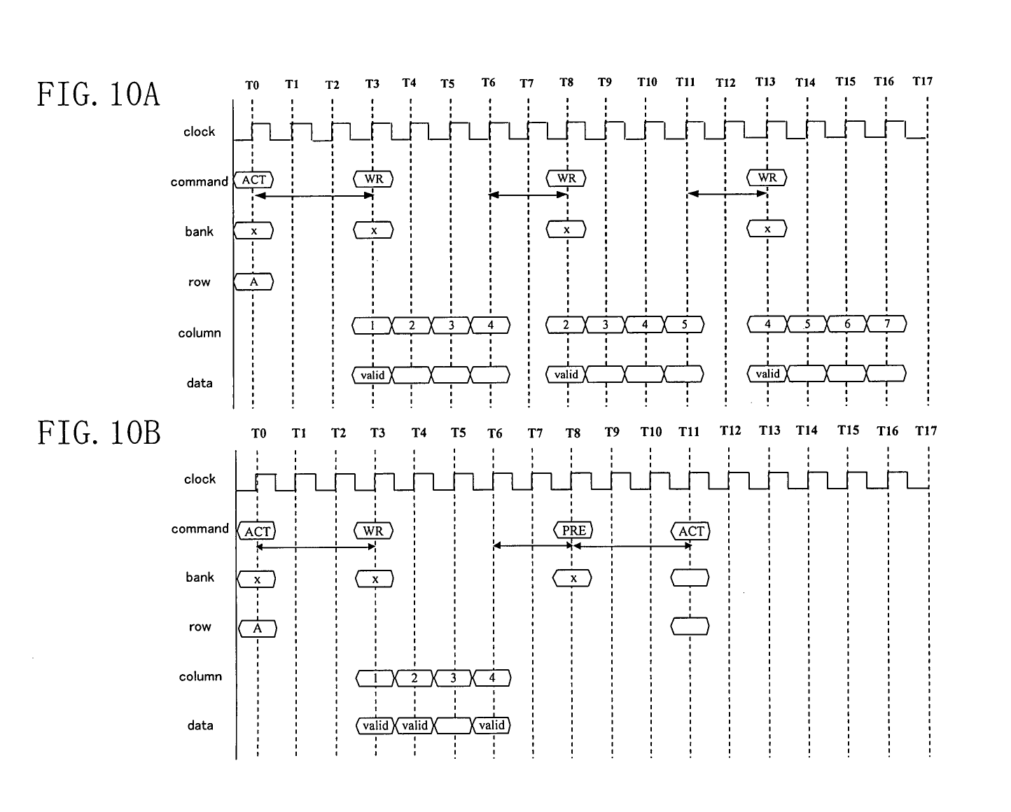

FIGS. 10A and 10B are timing charts for explaining an operation of the memory interface of this embodiment. FIG. 10A is a timing chart when memory access is separately performed with respect to three memory access parameters. In this case, at time T3, a write command for a first memory access parameter is issued and data is written into a column address “1”, and thereafter, at time T8, a write command for a second memory access parameter is issued and data is written into a column address “2”, and further, at time T13, a write command for a third memory access parameter is issued and data is written into a column address “4”. On the other hand, FIG. 10B is a timing chart when memory accesses for three memory access parameters are simultaneously performed. In this case, a write command for three memory access parameters is issued at time T3, and data is written into column addresses “1”, “2”, and “4”.

As described above, according to this embodiment, a plurality of memory access parameters for memory access to the same bank in an SDRAM are processed with one operation of burst transfer, so that the number of times of issuance of a command to the SDRAM is reduced, resulting in an improvement in memory access efficiency.

### SEVENTH EMBODIMENT

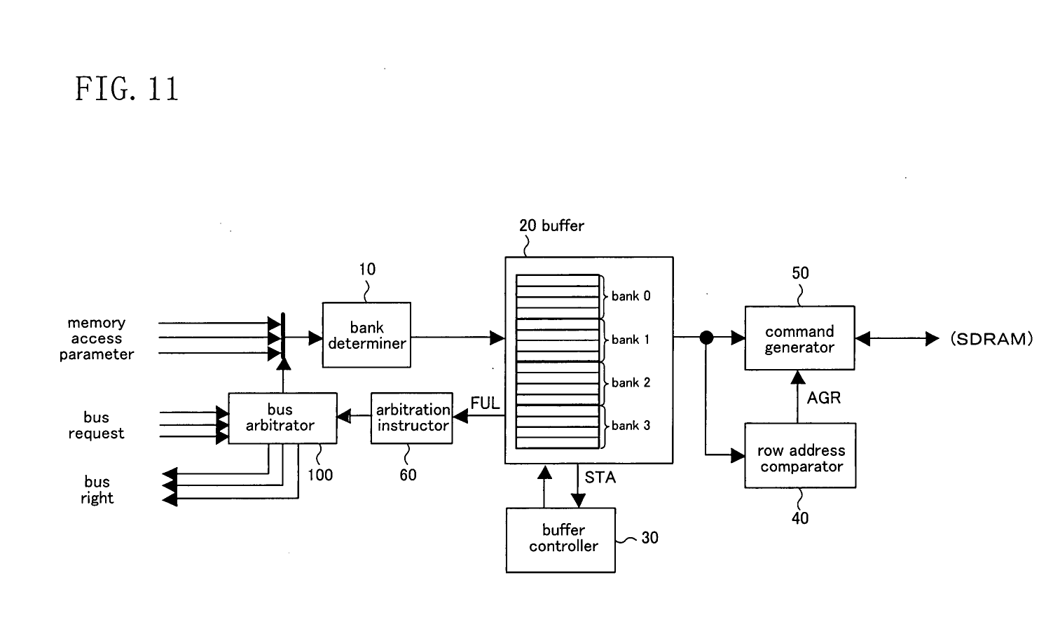

FIG. 11 illustrates a configuration of a memory interface according to a seventh embodiment of the present invention. The memory interface of this embodiment has the same configuration as that of the memory interface of the first embodiment, except that an arbitration instructor 60. Hereinafter, only a difference between the first and seventh embodiments will be described.

The arbitration instructor 60 references a fullness which indicates how much memory access parameters are accumulated in each block in the buffer 20, and instructs the bus arbitrator 100 to give a reduced priority to an access request to a bank corresponding to a block having a high fullness, and an increased priority to an access request to a bank corresponding to a block having a low fullness. Specifically, the arbitration instructor 60 receives a signal FUL indicating the fullness of each block from the buffer 20, and based on this, controls the bus arbitrator 100. For example, when the fullness of each of four blocks is represented by three levels, i.e., “high”, “intermediate”, and “low”, the signal FUL may be a signal of a total of eight bits (a two-bit signal indicating a fullness is provided for each of the four blocks).

As described above, according to this embodiment, a high priority is given to storage of a memory access parameter into a block having a low fullness in the buffer 20, and storage of a memory access parameter into a block having a high fullness is suppressed. Thereby, access requests are prevented from being concentrated into a specific bank in an SDRAM, so that a block having a high fullness is prevented from overflowing, thereby preventing a reduction in memory access efficiency.

### EIGHTH EMBODIMENT

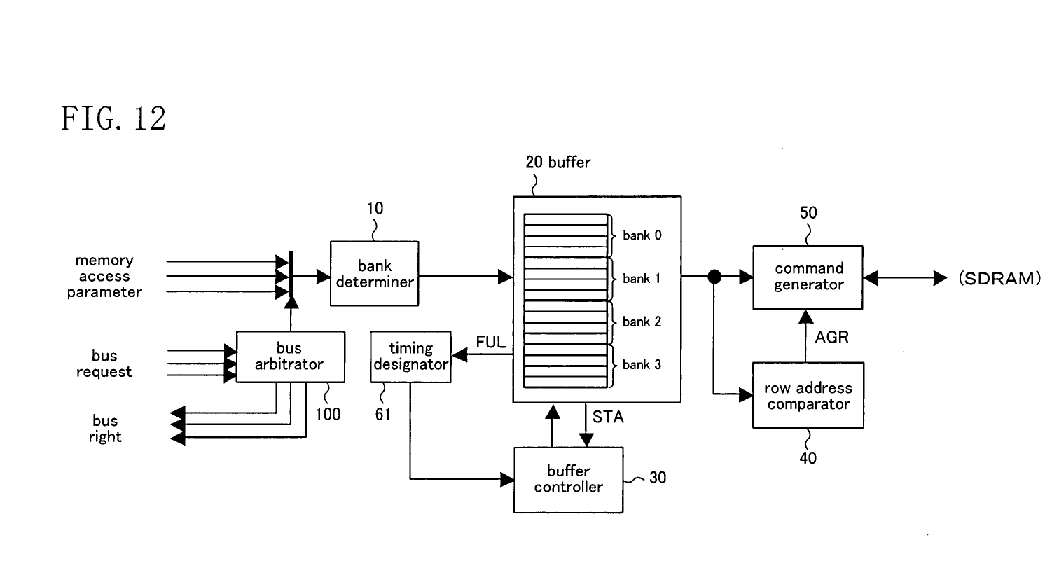

FIG. 12 illustrates a configuration of a memory interface according to an eighth embodiment of the present invention. The memory interface of this embodiment has the same configuration as that of the memory interface of the first embodiment, except that a timing designator 61 is additionally provided. Hereinafter, only a difference between the first and eighth embodiments will be described.

As described above, the buffer controller 30 performs an output control of the buffer 20 so that memory access parameters are successively output from a block selected in the buffer 20 until the selected block becomes empty or a maximum select time elapses. The timing designator 61 designates a maximum select time for each block with respect to the buffer controller 30. Specifically, the timing designator 61 receives the above-described signal FUL, and sets a maximum select time to be relatively long for a block having a high fullness, and sets a maximum select time to be relatively short for a block having a low fullness.

Also, a maximum select time for each block may be previously provided to the timing designator 61 using a CPU, a DSP, or the like, and the buffer controller 30 may select the blocks in accordance with the previously set maximum select times.

For example, when a large amount of memory access parameters are input for a short time, each maximum select time is preferably set to be relatively short. This is because, during the time when memory access parameters are output from a block selected by the buffer controller 30, a large amount of memory access parameters are stored into a block which is waiting for selection for a long time, so that the waiting block is likely to overflow. In such a case, by setting each maximum select time to be relatively short, there is no longer a block which is waiting for selection for a long time, thereby avoiding the overflow problem.

On the other hand, when only a small amount of memory access parameters are input for a long time, each maximum select time is preferably set to be relatively long. This is because, if the next block is selected before at least two memory access parameters are stored into a block, only one memory access parameter is output from the previously selected block, so that it is likely that the effect of improving memory access efficiency by removing the above-described step of generating a precharge command is not obtained. In such a case, by setting a maximum select time to be relatively long, a plurality of memory access parameters for access to the same bank in an SDRAM are consecutively output, thereby obtaining the effect of improving memory access efficiency.

As described above, according to this embodiment, the maximum select time for selection of blocks in the buffer 20 by the buffer controller 30 is dynamically or statically changed. Thereby, the overflow of each block in the buffer 20 is suppressed, thereby achieving more efficient memory access.

### NINTH EMBODIMENT

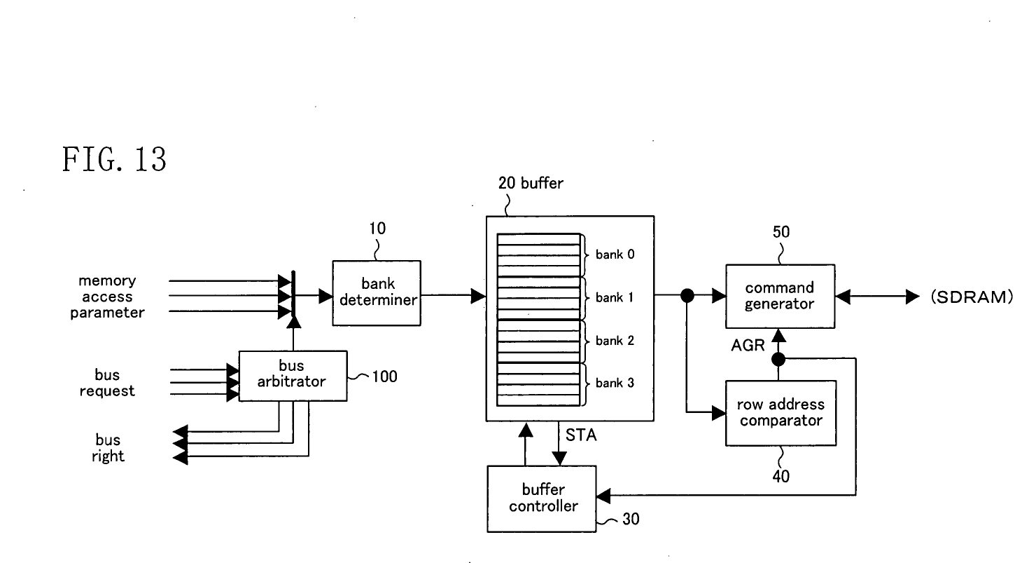

FIG. 13 illustrates a configuration of a memory interface according to a ninth embodiment of the present invention. The memory interface of this embodiment has the same configuration as that of the memory interface of the first embodiment, except that the signal AGR output from the row address comparator 40 is added to the operating conditions for the buffer controller 30. Hereinafter, only a difference between the first and ninth embodiments will be described.

When the buffer controller 30 receives the signal AGR having the Lo level, the buffer controller 30 selects the next block in the buffer 20, and performs an output control of the buffer 20 so that a memory access parameter is output from the selected block. In other words, the buffer controller 30 interrupts the output of consecutive memory access parameters from a selected block, and inserts a memory access parameter from another block.

When the command generator 50 receives the signal AGR having the Lo level, the command generator 50 generates a command for memory access for a memory access parameter output by interruption, earlier than generation of a command for memory access for the following memory access parameter not having the same row address.

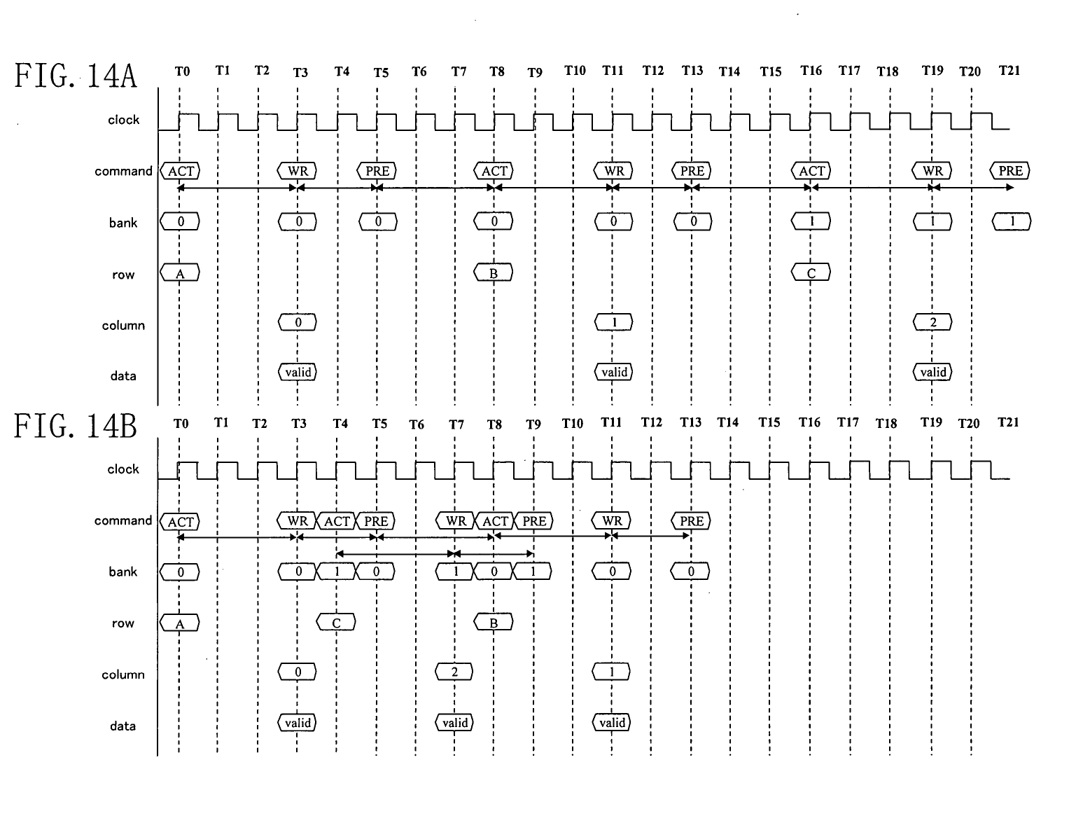

FIGS. 14A and 14B are timing charts for explaining an operation of the memory interface of this embodiment. FIG. 14A is a timing chart when an interruption output of a memory access parameter corresponding to another bank is not performed. In this case, at time T3, a write command is issued with respect to a row address “A” of a bank “0” (hereinafter referred to as an access A). At time T11, a write command is issued with respect to a row address “B” of the same bank “0” (hereinafter referred to as an access B). At time T16, a write command is issued with respect to a row address “C” of a different bank “1” (hereinafter referred to as an access C). Here, at time T5 which precedes the access B, a precharge command which is an end process of the access A is issued with respect to the bank “0”, and at time T8, an active command is issued with respect to the row address “B”, which is a preprocess for the access B. Thus, when memory accesses to different row addresses of the same bank are consecutively performed, a precharge command is issued (time T5) after a preceding memory access, and after a predetermined time interval specified in memory standards, an active command is issued with respect to a row address for the following memory access (time T8). In other words, after a command for preceding memory access is issued, a precharge command is issued, and thereafter, no memory access is performed with respect to the SDRAM until a predetermined time interval elapses.

On the other hand, FIG. 14B is a timing chart when an interruption output of a memory access parameter corresponding to another bank is performed. In this case, at time T3, a write command is issued with respect to a row address “A” of a bank “0”, and thereafter, at time T4, an active command is issued with respect to a row address “C” of a different bank “1” for a memory access parameter which is output earlier by interruption. Thus, an active command which is issued at as late as time T16 in the example (preceding example) of FIG. 14A, is issued at as early as time T4 at which memory access is not performed in the preceding example, in the example (following example) of FIG. 14B. Thereafter, at time T7, a write command for the access C is issued, and at time T11, a write command for the access B is issued, so that all the accesses A to C are ended earlier than the preceding example.

As described above, according to this embodiment, earlier than when a memory access parameter for access to the same bank and a different row address in an SDRAM, a memory access parameter for access to another bank is output by interruption, thereby improving memory access efficiency and system response.

### TENTH EMBODIMENT

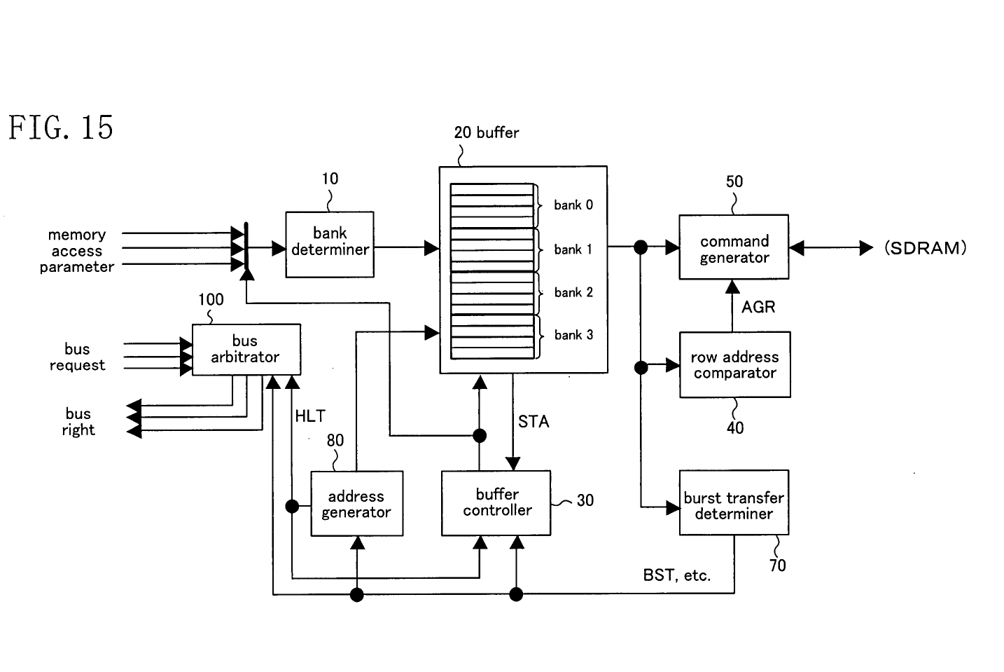

FIG. 15 illustrates a configuration of a memory interface according to a tenth embodiment of the present invention. The memory interface of this embodiment has the same configuration as that of the memory interface of the first embodiment, except that a burst transfer determiner 70 and an address generator 80 are additionally provided. Hereinafter, only a difference between the first and tenth embodiments will be described.

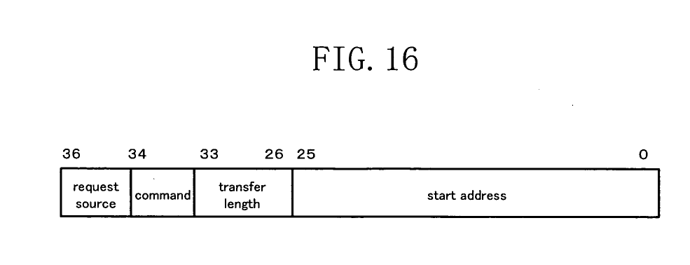

The burst transfer determiner 70 determines whether a memory access parameter output from the buffer 20 is transferred by single transfer in which the transfer length is one word, or burst transfer in which the transfer length is two or more words, and when determining that the memory access parameter is transferred by burst transfer, determines whether or not the memory access parameter is for a request for start of burst transfer. FIG. 16 illustrates an exemplary data structure of a memory access parameter for the burst transfer start request. For example, the memory access parameter for the burst transfer start request includes a start address, a command, a transfer length, and bus master determination information indicating information about a bus master (the request source), which are required for access to an SDRAM, and the like. The burst transfer determiner 70 determines a start address, a transfer length, and a request source bus master for the request, based on the memory access parameter for the burst transfer start request, and outputs a signal BST indicating whether burst transfer or single transfer is being performed. For example, the signal BST indicates that burst transfer is being performed when it is at a Hi level, and indicates that single transfer is being performed when it is at a Lo level.

When the address generator 80 receives the signal BST having the Hi level, the address generator 80 starts generating an address for burst transfer based on information of the burst transfer start address and the transfer length information output from the burst transfer determiner 70. Specifically, the address generator 80 has a counter (not shown), and generates addresses for burst transfer until data transfer is completed in an amount corresponding to the transfer length, starting from the start address, using the counter. Also, when the address generation corresponding to the transfer length is finished, or it is determined that a generated address is for access to another bank in the SDRAM, the address generator 80 outputs a signal HLT indicating the halt of burst transfer. For example, the signal HLT indicates that burst transfer is halted when it is at a Hi level, and indicates that burst transfer is being performed when it is at a Lo level.

When the bus arbitrator 100 receives the Hi-level signal BST, the bus arbitrator 100 gives a bus right to a bus master (not shown) which is a request source of burst transfer, based on information about the bus master output from the burst transfer determiner 70. Thereafter, the bus master acquiring the bus right withdraws the bus request, and when write access is performed, outputs data for the access to the memory interface. Also, when receiving the Hi-level signal HLT, the bus arbitrator 100 deprives the bus master of the given bus right.

The address generated by the address generator 80 is for burst transfer having a predetermined transfer length. For example, when the predetermined transfer length for burst transfer is eight words, the address generator 80 generates addresses which are incremented in units of an amount corresponding to eight words. In the case of burst transfer for write access, the address generator 80 stores the generated address together with data output by the bus master into a block corresponding to a bank for the write access in the buffer 20. In the case of burst transfer for read access, the address generator 80 stores the generated address into a block corresponding to a bank for the read access in the buffer 20. Note that the address generation performed by the address generator 80 may be started from timing with which the bus request from the bus master given the bus right is withdrawn.

When the buffer controller 30 receives the Hi-level signal BST, the buffer controller 30 performs an output control of the buffer 20 so that a memory access parameter is output from a block corresponding to a bank for burst transfer. When the buffer controller 30 receives the Hi-level signal HLT, the buffer controller 30 selects the next block, and performs an output control of the buffer 20 so that a memory access parameter is output from the selected block.

The command generator 50 receives a memory access parameter which is output from the buffer 20 by the control of the buffer controller 30, and based on this, generates a command for burst transfer.

As described above, according to this embodiment, even when the capacity of the buffer 20 is relatively small, a memory interface which supports burst transfer for a large amount of write data is achieved while improving memory access efficiency as in the first embodiment.

### ELEVENTH EMBODIMENT

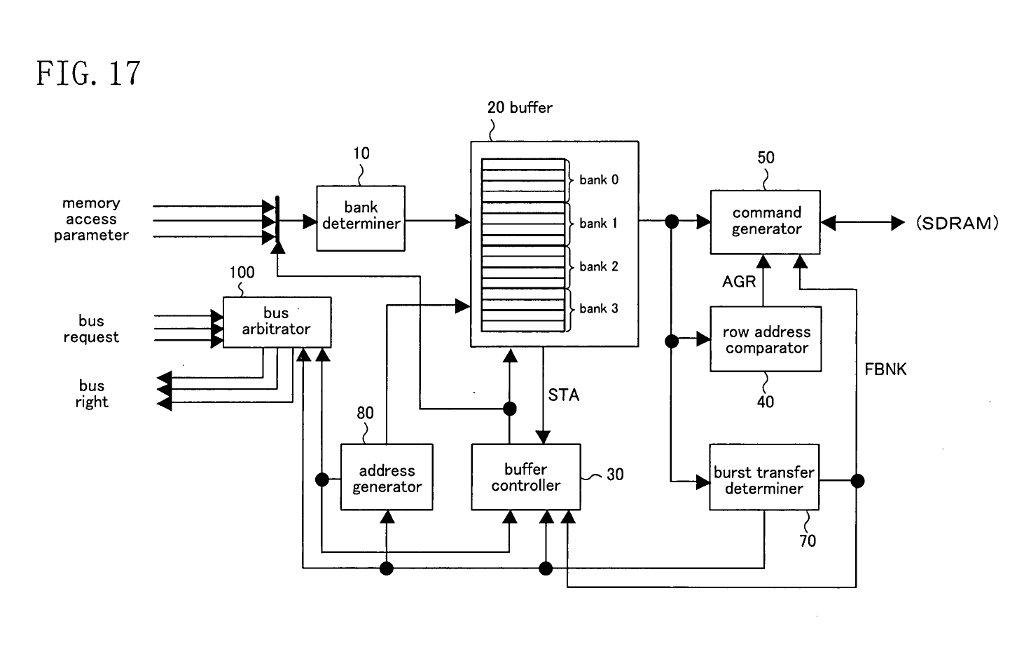

FIG. 17 illustrates a configuration of a memory interface according to an eleventh embodiment of the present invention. The memory interface of this embodiment has the same configuration as that of the memory interface of the tenth embodiment, except that a new function is added to the buffer controller 30, the command generator 50, and the burst transfer determiner 70. Hereinafter, only a difference between the tenth and eleventh embodiments will be described.

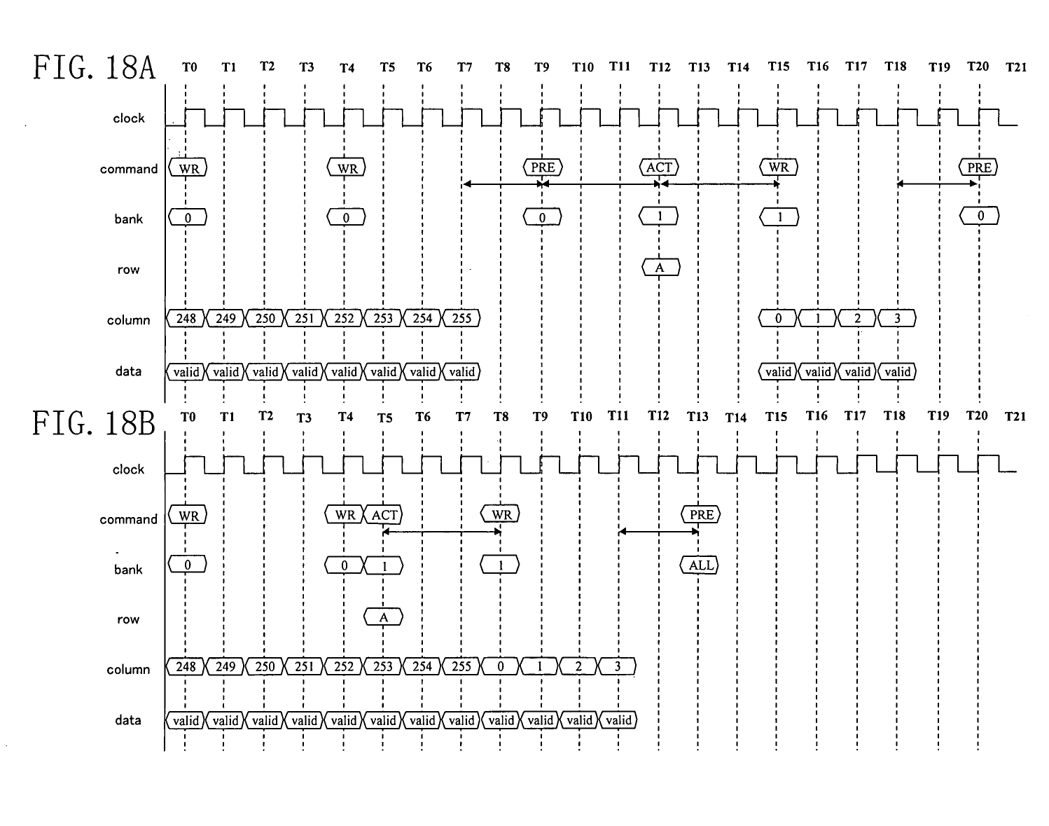

In the memory interface of the tenth embodiment, when a bank of an SDRAM to be accessed is switched until burst transfer requested by a bus master is completed, the burst transfer is temporarily suspended due to the bank switching process. For example, as illustrated in FIG. 18A, at time T7, write access for burst transfer to a bank “0” is ended, and thereafter, at time T9, a precharge command for the bank “0” is issued. At time T12, an active command is issued with respect to the next bank “1”. From time T15, write access for burst transfer to the bank “1” is resumed. Here, burst transfer is temporarily suspended from time T8 to time T14.

Therefore, in the memory interface of this embodiment, when burst transfer is performed over two banks, an active command is issued with respect to the next bank before, preferably immediately before, the end of access to the previous bank. Specifically, the burst transfer determiner 70 determines whether or not access to a certain bank in an SDRAM is ended by burst transfer having a predetermined transfer length (e.g., eight words long) for a memory access parameter output from the buffer 20, i.e., whether or not the burst transfer accesses the final address of the bank. When determining the end of the access, the burst transfer determiner 70 outputs a signal FBNK indicating the next bank.

The buffer controller 30 performs an output control of the buffer 20 so that a memory access parameter is output from a block corresponding to a bank indicated with the signal FBNK in the buffer 20. The command generator 50 generates an active command for the bank indicated with the signal FBNK, following the generation of a command for the memory access parameter output from the buffer 20. For example, as illustrated in FIG. 18B, at time T4, a write command for final burst transfer is issued with respect to a bank “0”, and thereafter, at time T5, an active command is issued with respect to the next bank “1”, and at time T8, a write command for burst transfer is issued with respect to the bank “1”.

Thus, it is determined whether or not access to a certain bank in an SDRAM, based on a memory access parameter for burst transfer, and an active command is issued with respect to the next bank in advance, thereby avoiding suspension of burst transfer, resulting in an improvement in memory access efficiency, as illustrated in FIG. 18B.

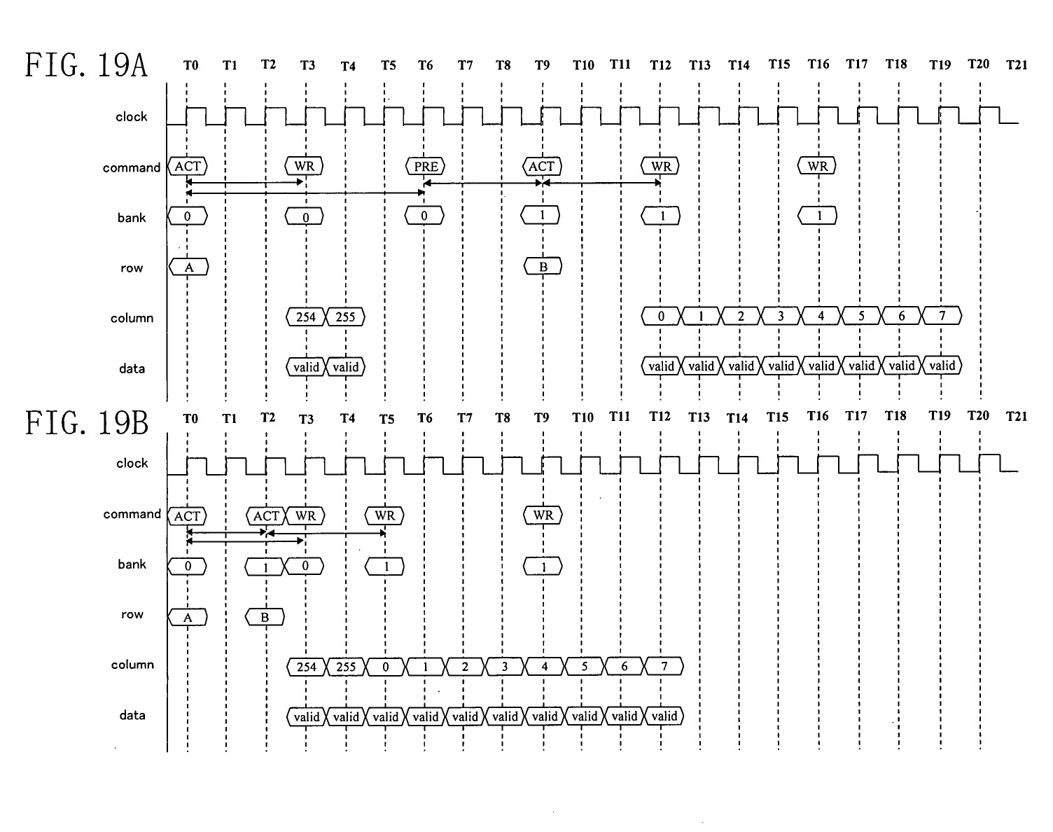

When burst transfer for a request from a certain bus master goes across a bank border in an SDRAM, particularly when burst transfer starts in the vicinity of the final address of a certain bank in an SDRAM (e.g., an address present within seven words counted from the final address of the bank when burst transfer has a predetermined transfer length of eight words), the burst transfer is temporarily suspended. For example, as illustrated in FIG. 19A, burst transfer is started from a start address represented by a bank “0”, a row “A”, and a column “254”. At time T0, an active command is issued with respect to the bank “0”. When first two-word data is completely transferred to the bank “0” at time T4, the burst transfer to the bank “0” is partway suspended, and preparation of access to the next bank “1” is started. Note that the predetermined transfer length of burst transfer is assumed to be four words. During this time, i.e., from time T5 to T11, memory access is not performed. In other words, burst transfer is temporarily suspended.

Therefore, also when burst transfer for a request from a certain bus master is started in the vicinity of the final address of a certain bank in an SDRAM, an active command is preferably issued with respect to the next bank in advance. Specifically, the burst transfer determiner 70 determines whether or not burst transfer having a predetermined transfer length goes across a bank border in the SDRAM, and when determining that the burst transfer goes across the bank border, outputs a signal FBNK indicating a bank present beyond the border. Note that, when it is determined that the burst transfer does not go across the bank border, the signal FBNK indicates a bank which is being currently processed. The command generator 50 consecutively generates active commands for a bank to which the start address of burst transfer for a request from a certain bus master belongs, and a bank indicated with the signal FBNK. For example, as illustrated in FIG. 19B, at time T0, an active command is issued with respect to a bank “0”, and thereafter, following this, at time T2, an active command is issued with respect to a bank “1”. Thereafter, at time T4, first two-word data is completely transferred to the bank “0”, and following this, at time T5 and thereafter, burst transfer is performed with respect to the bank “1”.

As described above, according to this embodiment, even when burst transfer goes across a bank border in an SDRAM partway therethrough, an active command is issued with respect to the next bank in advance, whereby burst transfer is not suspended, resulting in a further improvement in memory access efficiency.

### TWELFTH EMBODIMENT

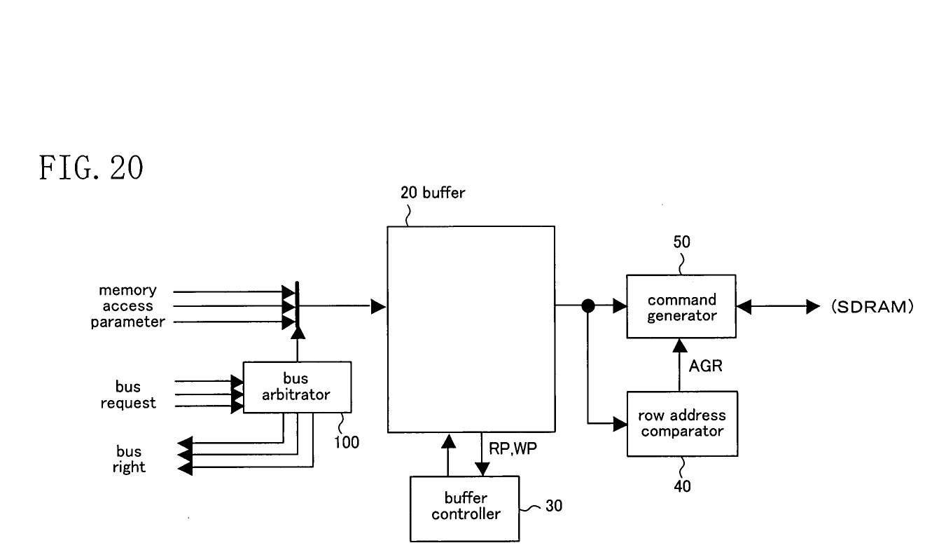

FIG. 20 illustrates a configuration of a memory interface according to a twelfth embodiment of the present invention. The memory interface of this embodiment comprises a buffer 20, a buffer controller 30, a row address comparator 40, and a command generator 50. Among them, the row address comparator 40 and the command generator 50 are similar to those of the first embodiment and will not be described. Hereinafter, only a difference between the first and twelfth embodiment will be described.

The buffer 20 stores a plurality of memory access parameters from a bus master. Preferably, the buffer 20 is a cyclic buffer. A memory access parameter is stored at any arbitrary storage place in the buffer 20.

The buffer controller 30 controls input and output of a memory access parameter with respect to the buffer 20 based on a read point and a write point corresponding to each bank in an SDRAM. Specifically, the buffer controller 30 stores memory access parameters into free space of the buffer 20 in order of input, and in this case, references a write pointer WP corresponding to a bank for the memory access parameter to designate a storage place. Memory access parameters are output from the buffer 20 in order of respective corresponding banks in the SDRAM. Specifically, the buffer controller 30 successively selects banks, and references read pointers RP corresponding to the selected banks to control output of memory access parameters. In other words, the buffer controller 30 performs an output control of memory access parameters in order of the respective corresponding banks in the SDRAM irrespective of the order of input of the memory access parameters.

Note that, when there are no memory access parameters to be output, or when a predetermined time has elapsed since the start of output of memory access parameters, the buffer controller 30 selects the next bank, and controls output of memory access parameters corresponding to the selected bank.

As described above, according to this embodiment, a memory access parameter corresponding to any arbitrary bank can be stored into any arbitrary storage place in a buffer, thereby making it possible to maximally utilize a limited buffer resource while improving memory access efficiency.

Although the above-described embodiments have been described using an SDRAM as an example, the memory interface of the present invention has the above-described effect with respect to a memory composed of a plurality of banks in addition to SDRAMs. Also, the bus arbitrator 100 may be provided either inside or outside the memory interface of the present invention.

What is claimed is:

1. A memory interface for controlling access of a plurality of bus masters to a multibank memory, comprising:
a buffer capable of storing a plurality of memory access parameters from the plurality of bus masters;
a buffer controller for performing an output control of the buffer so that the memory access parameters stored in the buffer are output in order of respective corresponding banks in the multibank memory; and
a command generator for generating a command for access to the multibank memory based on the memory access parameters output from the buffer,
wherein, when the command generator successively receives memory access parameters for access to the same bank and the same row in the multibank memory, the command generator skips generating a precharge command to be issued after memory access to the preceding memory access parameter.

2. The memory interface of claim 1, wherein:
the buffer is composed of a plurality of blocks corresponding to respective banks in the multibank memory;
the memory interface comprises a bank determiner for determining a bank for a memory access parameter input into the memory interface, and storing the memory access parameter into a block in the buffer corresponding to the determined bank; and
the buffer controller performs an output control of the buffer so that blocks are successively selected, and memory access parameters are consecutively output from the selected block.

3. The memory interface of claim 2, comprising:
a register for storing information about a configuration of the buffer,
wherein the buffer is composed of the plurality of blocks based on the information stored in the register.

4. The memory interface of claim 2, comprising:
a counter for counting the number of access requests to each bank in the multibank memory based on a result of the determination by the bank determiner,
wherein the buffer changes a size of each of the plurality of blocks for each predetermined time interval, based on a result of the count of the counter.

5. The memory interface of claim 2, comprising:
an arbitration instructor for referencing a fullness of each block in the buffer, and instructing a bus arbitrator to preferentially give a bus use right to a bus master which requests access to a bank corresponding to a block having a relatively low fullness, among the plurality of bus masters.

6. The memory interface of claim 2, comprising:
a timing designator for designating timing for selection of the blocks with respect to the buffer controller,
wherein the buffer controller successively selects the blocks in accordance with the timing designated by the timing designator.

7. The memory interface of claim 6, wherein the timing designator references a fullness of each block in the buffer, and designates the timing so that an output time of a memory access parameter from a block having a relatively high fullness is relatively long.

8. The memory interface of claim 2, comprising:
a command determiner for determining whether the input memory access parameter is for write access or read access,
wherein, when the command determiner determines that the input memory access parameter is for read access, the buffer controller preferentially selects a block in the buffer corresponding to a bank for the input memory access parameter which is a determination target of the bank determiner.

9. The memory interface of claim 8, comprising:
an overtake determiner for determining whether or not the input memory access parameter can be output earlier than a memory access parameter which is already stored in the buffer and is for access to the same bank in the multibank memory,
wherein, when the command determiner determines that the input memory access parameter is for read access, the overtake determiner references a memory access parameter already stored in a block in the buffer corresponding to a bank for the input memory access parameter which is a determination target of the bank determiner, and when the referenced memory access parameter is for write access to a row different from that for read access for the input memory access parameter, determines that the input memory access parameter can be output earlier than the referenced memory access parameter, and
the buffer controller performs an output control of the buffer so that the memory access parameter determined by the overtake determiner to be able to be output earlier is preferentially output from the preferentially selected block.

10. The memory interface of claim 1, comprising:
a row address comparator for comparing row addresses for two memory access parameters for access to the same bank in the multibank memory, the two memory access parameters being successively output from the buffer,
wherein, when the row address comparator indicates that the row addresses for the two memory access parameters are the same, the command generator skips generating the precharge command.

11. The memory interface of claim 10, wherein:
when the row address comparator indicates that the row addresses for the two memory access parameters are not the same, the buffer controller performs an output control of the buffer so that a memory access parameter corresponding to another bank in the multibank memory is output; and
when the row address comparator indicates that the row addresses for the two memory access parameters are not the same, the command generator generates a command for memory access for the memory access parameter corresponding to the other bank earlier than the command for memory access for the following memory access parameter.

12. The memory interface of claim 1, comprising:
an address increment calculator for calculating increments of addresses for the plurality of memory access parameters for access to the same bank in the multibank memory, the plurality of memory access parameters being successively output form the buffer; and
an increment summing section for summing the increments calculated by the address increment calculator,
wherein the command generator generates a command for transferring data corresponding to an address for a leading one of the plurality of memory access parameters, and following data corresponding to the sum of the increments calculated by the increment summing section, together in one access.

13. The memory interface of claim 1, comprising:
a burst transfer determiner for, when a memory access parameter for a burst transfer start request is output from the buffer, determining a start address, a transfer length, and a request source bus master for the request based on the memory access parameter; and
an address generator for generating addresses for burst transfer having a predetermined transfer length and successively storing the addresses into the buffer, until data transfer is completed in an amount corresponding to the transfer length from the start address, the transfer length and the start address being determined by the burst transfer determiner,
wherein the buffer controller performs an output control of the buffer so that a memory access parameter corresponding to a bank for burst transfer having the predetermined transfer length in the multibank memory is output.

14. The memory interface of claim 13, wherein:
the burst transfer determiner determines whether or not access to a bank in the multibank memory is ended by burst transfer having the predetermined transfer length for a memory access parameter output from the buffer;
the buffer controller performs an output control of the buffer so that, when the burst transfer determiner determines that the access is ended, a memory access parameter corresponding to the next bank in the multibank memory is output; and
the command generator, when the burst transfer determiner determines that the access is ended, generates an active command for the next bank, following generation of a command for a memory access parameter output from the buffer.

15. The memory interface of claim 13, wherein:
the burst transfer determiner determines whether or not burst transfer having the predetermined transfer length goes across a bank border in the multibank memory;
the buffer controller performs an output control of the buffer so that, when the burst transfer determiner determines that the burst transfer having the predetermined transfer length goes across the bank border, a memory access parameter corresponding to a bank beyond the border in the multibank memory is output; and
the command generator, when the burst transfer determiner determines that the burst transfer having the predetermined transfer length goes across the bank border, generates an active command for the bank beyond the border before generation of a command for the burst transfer having the predetermined transfer length.
